(19) United States
(12) Patent Application Publication
(10) Pub. No.: US 2007/0183543 A1
(43) Pub. Date: Aug. 9, 2007

(54) Power line communication (PLC) noise isolation device

(76) Inventor: Yung-Wei Lu, Taipei City (TW)

Correspondence Address: TROXELL LAW OFFICE PLLC, SUITE 1404, 5205 LEESBURG PIKE, FALLS CHURCH, VA, 22041, US

(21) Appl. No.: 11/346,340

(22) Filed: Feb. 3, 2006

(51) Int. Cl. H03D 1/04; G05B 11/01; G08B 1/08

(52) U.S. Cl. 375/346; 340/538; 340/310.13

(57) ABSTRACT

This invention is to reveal a kind of noise isolation device designed on the power plug. In particular, a kind of power line communication noise isolation device. The purpose is to filter noises existing in the power line using environment through the use of a filter circuit and, at the same time of improving power line communication signal quality, the power line communication device could be connected to power plug together with other electrical appliances at the same time for the increase of convenience.

### FIELD OF THE INVENTION

This invention is about a kind of noise isolation device, in particular, a kind of power line communication isolation device for use with power plug.

### BACKGROUND OF THE INVENTION

The prevalence of Internet has brought tremendous changes to mankind. In particular, the application of communication has reached the convenience that has achieved never before.

In the application of Internet in recent years, the development of wireless network is growing at fast speed. If use wishes to turn on computer to use Internet at any corner of the house, office, or even a factory, he only need to transmit signal through Access Point (AP). However, AP's needs to go through physical network before it becomes active. Unless the network layout and floor plan has already been added, it is necessary to construct network wiring separately to the required location. This has created a big problem in applications.

In view of above problem, presently there are already Power Line Communication (PLC) technology that could provide solutions. The basic concept of PLC is “Without new cable” by using the existing power line available in home and office to construct Internet.

By connecting the PLC external outlet to the USB or Ethernet port on the computer and then plug into the power plug on the wall of building, the information from computer can be converted to signal and transmitted through power line similar to the power line available in the present day.

However, there is still a problem exists in the PLC used presently. As the quantities of power plug in the ordinary buildings are still limited and these power plugs are usually plugged with electrical appliances in use, communication interference will result when these electrical appliances are used together with the PLC devices. If these appliances are unplugged when using PLC devices, it will create significant inconvenience in life.

From here it can be seen that the problem and deficiency derived from above conventional technology is not a good design and needs improvement.

In view of the problems and deficiency derived from above conventional technology, the inventor attempts to improve and innovate. After many years of research, finally this invention of PLC noise isolation device is completed.

### SUMMARY OF THE INVENTION

The purpose of this invention is in providing a kind of power line communication isolation device for the isolation of noise when the PLC device is connected to the power plug together with electrical appliances in order to improve the communication quality of the PLC device.

Another purpose of this invention is in providing a kind of PLC isolation device for the filtering of high frequency communication signal and further to provide electrical interface for electrical appliance to use without the need to unplug other electrical appliances in use.

Still another purpose of this invention is to provide a kind of PLC noise isolation device with the advantages of simple installation and convenient to use.

To achieve above mentioned purposes of PLC noise isolation device, this invention is to reveal a kind of noise isolation device installed on the power plug, in particular a kind of PLC noise isolation device; the purpose of the device is to filter the noise in the PLC using environment through a filter circuit, and, at the same time of improving quality of PLC signal, connect the PLC device with other electrical appliances on the same power plug and increase the convenience in usage.

### BRIEF DESCRIPTION OF THE DRAWINGS

FIG. 1 shows the first embodiment of the PLC noise isolation device of this invention.

FIG. 2 shows another embodiment of the PLC noise isolation device of this invention.

### DETAILED DESCRIPTION OF THE PREFERRED EMBODIMENTS

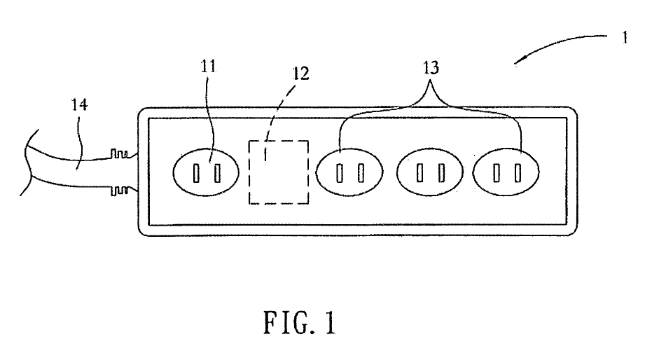

FIG. 1 shows the first preferred embodiment of the PLC noise isolation device of this invention. The figure shows the application of this invention on power plug 1, where a power line 14 is used to transmit power and signal; a PLC device (not shown) can be plugged into PLC device interface 11 in order to transmit and convert signal, transmit a wireless signal in order to provide the wireless receiving device that requires to receive this wireless signal. The wireless signal thus can extend the transmission range through wireless method through the transmission of power line 14; other electrical appliances are plugged onto the electrical power interface 13 in order to secure the needed power. The PLC noise isolation device 12 of this invention installed between the PLC device interface 11 and electrical power interface 13 for isolation of noise that could influence other electrical appliance. When PLC device and other electrical appliance are plugged onto PLC device interface 11 and electrical power interface 13 respectively, other appliances will generate noise when requiring power and affect the quality of PLC device. The specs of frequency signal used in normal PLC is between 2 and 30 MHz or between 2 and 34 MHz, therefore the action of PLC noise isolation device 12 will only filter the signal in this frequency band and prevent the said noise from influencing signals of PLC device and enable other appliances to use continuously without being affected.

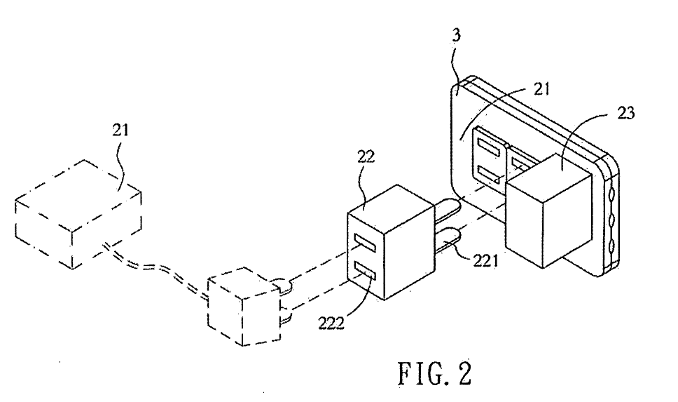

FIG. 2 shows another preferred embodiment of PLC noise isolation device of this invention. The figure shows the application of this invention in power plug 3 where PLC noise isolation device 22 is connected to a power plug 3 through a terminal 221; the socket 222 on the other end can be connected to the plug of electrical appliance 21 and isolates high frequency noise through the said PLC noise isolation device 22; in addition, PLC device 23 is connected to the said power plug 3 and transmit signals; isolate signals of specific frequency bandwidth through the PLC noise isolation device 22 for the electrical appliance 21 to continue being used.

Through above stated preferred embodiment it can be seen that the purpose of the PLC noise isolation of this invention can depending on the need be installed into power plug, or inserted into power plug using external connection method in order for the use of PLC device and electrical appliance at the same time.

Above detailed description is aiming at concrete explanation of a preferred embodiment of this invention. However, the said embodiment is not limited to the claim of this invention. All equivalent embodiments or modifications not deviating from the spirit of the art of this invention are all included in the range of the patent of this invention.

In summary, this case is indeed not only innovative in the technical thinking but also has more items of added improvement than the conventional products that is sufficient in meeting the innovation and advanced legal creative patent requirement. I hereby file the application and request your institution in granting the new patent application for the encouragement of this invention. I appreciate your kind consideration.

What is claimed is:

1. A kind of power line communication (PLC) noise isolation device, including a PLC device and an electrical appliance connecting to the same power plug at the same time; a electrical power interface installed between the said electrical appliance PLC device and the said power plug; and
a PLC noise isolation device installed on the said power plug; a filter circuit is installed inside; the said PLC noise isolation device is electrically connected to the said power interface; as the electrical current and signals passing power interface through filter circuit, the signals of specific bandwidth are isolated by the said filter circuit, preventing the said noise from affecting the said PLC device.

2. A kind of PLC noise isolation device as stated in claim 1 of the patent application, where the communication protocol used by the said PLC noise isolation device meets the specs of Homeplug.

3. A kind of PLC noise isolation device as stated in claim 1 of the patent application, where the power supplied by the power plug is alternating current.

4. A kind of PLC noise isolation device as stated in claim 1 of the patent application, where the specific bandwidth isolated by the filter circuit is between 2 and 30 MHz.

5. A kind of PLC noise isolation device as stated in claim 1 of the patent application, where the specific bandwidth isolated by the filter circuit is between 2 and 34 MHz.

6. A kind of PLC noise isolation device including a terminal and a socket; the internal of the said PLC noise isolation device is installed with a filter circuit for filtering high frequency signals.

7. A kind of PLC noise isolation device as stated in claim 6 of the patent application, where the said power plug is for the connection of the said electrical appliance.

8. A kind of PLC noise isolation device as stated in claim 6 of the patent application, where the said terminal is for connection to the said power plug.
